(19) United States
(12) Patent Application Publication
(10) Pub. No.: US 2024/0347670 A1
(43) Pub. Date: Oct. 17, 2024

(54) METHOD AND OPTOELECTRONIC DEVICE

(71) Applicant: ams-OSRAM international GmbH, Regensburg (DE)

(72) Inventors: Christoph Klemp, Regensburg (DE); Stefan IIIek, Donaustauf (DE); Ines Pietzonka, Donaustauf (DE); Andreas Biebersdorf, Regensburg (DE); Xue Wang, Regensburg (DE)

(21) Appl. No.: 18/683,884

(22) PCT Filed: Aug. 16, 2022
(86) PCT No.: PCT/EP2022/072883

§ 371 Date: Feb. 15, 2024

Related U.S. Application Data
(63) Continuation of application No. PCT/EP2021/072901, filed on Aug. 18, 2021.

(51) Int. Cl. H01L 33/14; H01L 33/00; H01L 33/02; H01L 33/06; H01L 33/30

(52) U.S. Cl. CPC H01L 33/14; H01L 33/0062; H01L 33/025; H01L 33/06; H01L 33/305

(57) ABSTRACT

In an embodiment a method includes providing a growth substrate layer, depositing a first doped [(AlₓGa₁₋ₓ)_{y}In_{1-y}]_{z}P_{1-z} carrier transport layer on the substrate layer with x in a range of [0.5;1] along a growth direction, and depositing an active region along the growth direction, the active region for generating radiation and comprising a plurality of alternating [(AlₐGa₁₋ₐ)_{b}In_{1-b}]_{c}P_{1-c} quantum well layers and [(Al_{d}Ga_{1-d})ₑIn₁₋ₑ]_{f}P_{1-f} barrier layers, wherein a is in a range of [0;0.5] and d is in a range of [0.45;1.0], wherein depositing of at least one of the barrier layer and/or the quantum well layer comprises doping with a dopant having a concentration in a range of 1e¹⁵ atoms/cm³ to 5e¹⁷ atoms/cm³, wherein the dopant is selected from at least one of the group consisting of Mg, Zn, Te and Si or depositing a second doped carrier transport [(AlₓGa₁₋ₓ)_{y}In_{1-y}]_{z}P_{1-z} layer with x in a range of [0.45;1] along the growth direction.

### CROSS-REFERENCE TO RELATED APPLICATIONS

This patent application is a national phase filing under section 371 of PCT/EP2022/072883, filed Aug. 16, 2022, which claims the priority of WO patent application PCT/EP2021/072901, filed Aug. 18, 2021, each of which is incorporated herein by reference in its entirety.

### TECHNICAL FIELD

The present invention relates to a method for manufacturing an optoelectronic device. The present invention also relates to an optoelectronic device.

### BACKGROUND

Optoelectronic devices also referred to as lighting diodes or LEDs require a supply of energy for illumination. The charge carriers introduced in an active zone of the optoelectronic device recombine under the emission of light. The recent decrease in size has led to the development of μ-LEDs, whose size lies in the area or less than 1000 μm² and can go down to about 10 μm². At such sizes, avoiding the reduction of quantum efficiency due to surface recombination is of paramount importance to enable such a device to emit light at small as well as larger currents. In addition, degradation of the device's performance has been observed, which also seems to depend on the amount of current flowing through the device.

### SUMMARY

The inventors have realized that in optoelectronic devices based on the InGaAlP material system a performance increase can be achieved by intentionally low level doping of the active zone of the device. Further, a relationship between the Al content and the low level doping has been observed such that the efficiency gain due to low level doping increases up to certain levels of Al content in the quantum barrier of the active zone. This performance increase may be explained by improved carrier injection into the quantum well stack. While such increase is independent of the size of the device, its effect is more relevant with shrinking device sizes and can be combined with other measure to improve the performance.

Embodiments provide a method for manufacturing an optoelectronic device. After providing a growth layer, i.e. based on GaAs or any other suitable material, a first doped carrier transport [(AlₓGa₁₋ₓ)_{y}In_{1-y}]_{z}P_{1-z} layer is deposited on the substrate layer with x in the range of [0.5;1] along a growth direction. The content of Al may vary depending on the needs and requirements as well as on the desired wavelength of the device. Then, an active region is deposited along the growth direction. The active region is configured to generate radiation and comprises a plurality of alternating [(AlₐGa₁₋ₐ)_{b}In_{1-b}]_{c}P₁₋ₑ quantum well layers and [(AlₐGa_{1-d})ₑIn₁₋ₑ]_{f}P_{1-f} barrier layers. Parameter “a” is in the range of [0;0.5] and parameter “d” is in the range of [0.45;1], in particular in the range of [0.60; 1.0] and in particular between 0.75 and 1.0. A second doped carrier transport [(AlₓGa₁₋ₓ)_{y}In_{1-y}]_{z}P_{1-z} layer is then deposited with x in the range of [0.45;1] along the growth direction.

Parameters y and z may be in the range of [0.45;0.55] and b and c are in the range of [0.45;0.55].

In accordance with the proposed principle, the active region will be doped with a dopant. For this purpose, a dopant having a concentration in the range of 1e15 atoms/cm³ to 5e17 atoms/cm³, particularly in the range of 1e16 atoms/cm³ to 1e17 atoms/cm³ and in particular in the range of 2e16 atoms/cm³ to 7e16 atoms/cm³ is added during the deposition of at least one of the quantum well layers and/or the barrier layers. The dopant may be selected from the group of Mg, Zn, Te and Si.

In some instances, the In content [(AlₐGa₁₋ₐ)_{b}In_{1-b}]_{c}P_{1-c} quantum well layers and [(AlₐGa_{1-d})ₑIn₁₋ₑ]_{f}P_{1-f} barrier layers, that is the parameter 1-b and 1-e are selected such that they are different. For example, parameter 1-b may range between 20% (1-0.8) to 60% (1-0.2) and particularly between 40% and 60%. Likewise, the In content for the barrier layers might be different or equal compared to the quantum well layers. The In content affects the bandgap, but also changes the lattice constant. Changing the In content during the deposition of a multi-quantum well structure may therefore induce some strain into the multi-quantum well structure.

Consequently, in some aspects, the in content of each barrier layer is equal but different compared to an adjacent quantum well layer. In some aspect, the difference in the In content in adjacent quantum well and quantum barrier layer will induce a strain, that may range between −4000 ppm to +4000 ppm. In some aspects, the In content in the barrier layers is smaller than the In content in the quantum well layer, inducing an overall strain, but also increasing the bandgap for the barrier layers.

As an overall result, the In content, the thickness or the Al content may vary when comparing the barrier layer and the quantum well layer. Hence, at least two parameters are different between a barrier layer and an adjacent quantum well layer in some aspects, said parameters selected from thickness, Al content and In content. In some further aspects, these parameters are also different for the respective barrier and/or quantum well layers. For example, some barrier layer may have a different In content or a different thickness compared to other barrier layers. This can induce a gradual change of parameters, thus inducing a gradual change of strain within the active region.

With the proposed method, an additional dopant is induced intentionally in at least one of the barrier and/or quantum well layers in the active region. It has been found that the efficiency of the device is increased by this additional and intentional doping. It should be noted that unintentional doping during deposition usually takes place, but such unintentional doping comprises a much lower concentration compared to the intentionally induced doping. Furthermore, it has been observed that higher doping than between 1e16 atoms/cm³ and 5e17 atoms/cm³ is detrimental and will result in a decrease of efficiency and performance.

Consequently, possible dopant concentrations may be in the range 1e16 atoms/cm³ to about 4e17 atoms/cm³, but more preferably in the range of 2e16 atoms/cm³ to 2e17 atoms/cm³ or in particular between 5e16 atoms/cm³ and 1.5e17 atoms/cm³. Other doping concentrations as stated in this application are suitable as well. It has also been found that the dopant could vary and that more than one dopant can be induced at the above-mentioned concentrations into the active region. The doping level of each dopant can be smaller than 5e17 atoms/cm³. The quantum well layer and the barrier layers can be doped with different dopants each. Likewise, the doping concentration can vary between barrier layers and adjacent quantum well layers. For example, the doping concentration for a barrier layer may be lower than for a respective quantum well layer. Likewise, different dopant materials may be used when depositing or growing the quantum well layer and the barrier layer, respectively.

In some instances, the doping concentration may vary in adjacent layers and also between layers of the same type that is quantum well layer or barrier layer. Typical dopants for such purpose could be Te, Zn, Si, Mg and the like.

This intentional doping may be about the order of 10 to 100 times larger than the unintentional inherent dopant concentrations within the material. In this regard, the expression “unintentional doping” does not only include doping with material impurities, but also all other impurities and native defects.

In some aspects, the deposition of the dopant is performed during depositing the material for at least one quantum barrier layer in the active region. The deposition of the dopant may also occur over a plurality of layer or every second or third layer. In some further aspects, the concentration of the dopant being added may vary during the step of doping. Consequently, it may be suitable to dope barrier layers and/or quantum well layers closer to the carrier transport layers with a different concentration than the barrier layers and quantum well layers located centrally within the active region. In some other aspect the doping concentration may increase or decrease towards one of the carrier transport layers, i.e. the concentration of dopants during depositing the quantum well layers and barrier layers may increase or decrease along the growth direction.

Depositing an active region may comprise depositing between 3 and 30 quantum well layers, whereas the quantum well layers each comprise a thickness between 2 nm und 15 nm and the quantum barrier layers each comprise a thickness between 3 nm und 25 nm. This will generate about 7 (3 quantum well layers and 4 barrier layers) to 61 alternating layers in the active region. Thickness as well as dopant concentration may vary when depositing the layers as discussed above.

In some aspects, at least some of the plurality of barrier layers comprise different Al content with respect to each other, wherein the Al content in each barrier layer is constant. Alternatively, a minimum and maximum Al content within the active region is different by a factor in the range of 1.1 to 3.5. For example, the Al content of a quantum well layer may be in the range of 0.0 to 0.5 (x in the range of [0.0;0.5]) and within the barrier layer in the range of 0.6 to 1. The thickness for at least some of the barrier layers may vary, wherein a minimum and a maximum thickness of the barrier layers in the active zone differ by a factor between 1.5 and 6.

In some aspects, the addition of the dopant during the deposition of a quantum well layer or a barrier layer is slightly delayed in respect to the actual deposition of the respective layer. For example, doping with the dopant takes place after depositing of the material for the at least one of the barrier layer and the quantum well layer has started. Hence, some of the respective layer has already been grown before the dopant is added. Likewise. In some aspects, adding of the dopant may end prior to stopping the depositing of the material for the at least one of the barrier layer and the quantum well layer.

It has been found that although only a single layer is doped, or only certain layers are doped, dopants are diffusing into adjacent layers. Consequently, an optoelectronic device manufactured with the above process may show a concentration variation in the dopant over several layers in the active region, referred to as dopant modulation. Consequently, in some aspects a dopant modulation is proposed by either changing the dopant in adjacent layers and/or in some other aspects providing an annealing step. This annealing step can be performed during deposition of the active region or after the active region is formed. In some aspects, a plurality of such steps can be performed after respective depositing steps of the material for the barrier and quantum well layers.

In some further aspects, un-doped AlGaInP layers may be deposited adjacent to the active region that is between the active region and the doped carrier transport layers. The Al content may vary with regard to the Al content of the adjacent carrier transport layer or the adjacent first layer of the active region. In some aspect, the Al content may be the same as the adjacent carrier transport layer.

Some other aspects concern a further improvement of the efficiency of the device, which is particularly suitable when combined with the intentional doping of the active region. In some aspects, a structured mask layer is deposited. In some aspects, the second transport layer can be structured as well to fulfil the purpose of the structured mask layer. Then another dopant is deposited and diffused through the second doped carrier transport [(AlₓGa₁₋ₓ)_{y}In_{1-y}]_{z}P_{1-z} layer into the active region. The additional doping will result in quantum well intermixing in those areas with increased dopant concentration resulting in a lateral energy barrier for the charge carriers injected into the masked area. The location of the intermixed areas is selected such that the various semiconductor layers can be separated within those areas resulting in a device edge with adjacent quantum well intermixing. Due to the induced energy barrier charge carriers are prevented from recombining non-radiatively along the edges of the device increasing the performance. It was found that the combination of both measures will improve the performance beyond the sum of the individual measures.

Depositing and diffusion of this additional dopant, in particular Zn can be achieved by various means. In some aspects, the dopant is deposited at a first temperature and diffused at a second temperature, the second temperature higher than the first temperature. This approach may control the diffusion of the dopant into the material. In some aspects, AsH₃ or any other As containing gas can be applied during the diffusion process enabling Ga or other III-type material to be saturated by the offered As.

Some further aspects are related to an optoelectronic device in accordance with the proposed principle of an intentional low level doping in the active region. Such optoelectronic device comprises a first doped carrier transport [(AlₓGa₁₋ₓ)_{y}In_{1-y}]_{z}P_{1-z} layer with x in the range of [0.5;1] and a second doped carrier transport [(AlₓGa₁₋ₓ)_{y}In_{1-y}]_{z}P_{1-z} with x in the range of [0.5;1]. The parameter x refers to the Al content and can be constant in both layers, different in the respective transport layers, but also vary along a certain direction.

Between both layers, an active region is arranged, which comprises a plurality of alternating [(AlₐGa₁₋ₐ)_{b}In_{1-b}]_{c}P_{1-c} quantum well layers and [(AlₐGa_{1-d})ₑIn₁₋ₑ]_{f}P_{1-f} barrier layers, wherein “a” is in the range of [0;0.5] and “d” is in the range of [0.55;1], in particularly in the range of [0.60; 0.90] and in particular between 0.75 and 0.85. At least one of the plurality of quantum well layers and the barrier layers comprises an intentionally induced dopant having a concentration in the range of 1e16 atoms/cm³ to 1e17 atoms/cm³ and in particular in the range of 2e16 atoms/cm³ to 7e16 atoms/cm³ with the dopant selected from at least one Mg, Zn, Te and Si.

In some aspects, the active region comprises between 3 and 30 quantum well layers, whereas the quantum well layers each comprise a thickness between 2 nm und 15 nm and the quantum barrier layers each comprise a thickness between 3 nm und 25 nm. Some of the barrier layers are doped, but the doping concentration may vary between quantum well layers and barrier layers. This is referred to as modulation of the dopant concentration. For example, the quantum well layers may comprise a lower but still intentional doping level than the barrier layers. Consequently, the dopant in the active region extends over a plurality of alternating quantum well layers and barrier layers. The expression “intentional doping” or “intentional doping level” refers to a concentration of dopant much larger (i.e. at least 10 times) than the unavoidable impurities in the material of the active region. The concentration of dopant may therefore vary between the different layers, but may also decrease or increase towards one of the first and second charge transport layers.

In some aspects, the dopant concentration may be largest within a central layer stack of the active region. In some further aspects, the device may further comprise an undoped layer arranged between at least one of the first doped carrier transport layer and the active region and the active region and the second doped carrier transport layer. In some further aspects, the Al content may not only vary between barrier and quantum well layers but also between adjacent barrier layers. For example, in some aspects a minimum and maximum Al content within the active region is different by a factor in the range of 1.1 to 1.7.

The performance of a device in accordance with the proposed principle can be further improved by quantum well intermixing in areas located close to the edges of the device. In some aspects, the optoelectronic device further comprises a quantum well intermixed area having a dopant concentration larger than the dopant concentration in the active region, the dopant particularly comprising Zn, but may also contain Mg. The quantum well-intermixed area is adjacent to an edge interface of the optoelectronic device.

### BRIEF DESCRIPTION OF THE DRAWINGS

Further aspects and embodiments in accordance with the proposed principle will become apparent in relation to the various embodiments and examples described in detail in connection with the accompanying drawings in which

FIG. 1 shows an embodiment of an optoelectronic device in accordance with some aspects of the proposed principle;

FIG. 2 illustrates the dopant concentration across the active region in an embodiment of an optoelectronic device in accordance with the proposed principle;

FIGS. 3A to 3I illustrate various steps of an embodiment for manufacturing an optoelectronic device in accordance with some aspects of the proposed principle;

FIG. 4 illustrate a diagram showing the performance improvement of optoelectronic devices according to the proposed principle in comparison to optoelectronic devices with unintentional doping;

FIG. 5 illustrates an example of the doping process of an optoelectronic device to illustrate some aspects of the present disclosure; and

FIG. 6 is an exemplary embodiment of an optoelectronic device to illustrate some aspects of the present disclosure.

### DETAILED DESCRIPTION OF ILLUSTRATIVE EMBODIMENTS

The following embodiments and examples disclose different aspects and their combinations according to the proposed principle. The embodiments and examples are not always to scale. Likewise, different elements can be displayed enlarged or reduced in size to emphasize individual aspects. It goes without saying that the individual aspects of the embodiments and examples shown in the Figures can be combined with each other without further ado, without this contradicting the principle according to the invention. Some aspects show a regular structure or form. It should be noted that in practice slight differences and deviations from the ideal form or shape may occur without, however, contradicting the inventive idea.

In addition, the individual figures and aspects are not necessarily shown in the correct size, nor do the proportions between individual elements have to be essentially correct. Some aspects are highlighted by showing them enlarged. However, terms such as “above”, “below” “larger”, “smaller” and the like are correctly represented with regard to the elements in the figures. So it is possible to deduce such relations between the elements based on the figures.

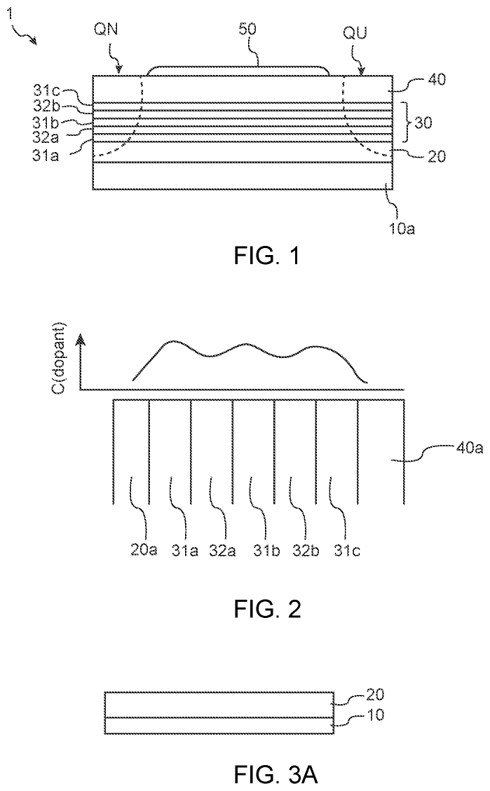

FIG. 1 illustrates an embodiment of an optoelectronic device 1 in the AlGaInP material system implementing a low-doped active region in accordance with the present invention. The optoelectronic device 1 comprises an n-type contact layer 10a, followed by an n-type carrier distribution and transport layer 20. Contact layer 10a can be made of metal or any other suitable material. Carrier transport layer 20 is based on the AlGaInP material system with Te or Si as dopants. An active region 30 is arranged on top of n-type carrier transport layer 20 and comprises an alternating plurality of quantum well layers 32a, 32b and barrier layers 31a, 31b and 31c.

In particular, a first barrier layer 31a of the active region is adjacent to carrier transport layer 20. Then, a quantum well layer 32a is arranged on the first barrier layer 31a, followed by a second barrier layer 31b. This structure of alternating barrier layers and quantum well layers is repeated until the last barrier layer 31c.

On top of the last barrier layer 31c, a p-type charge carrier transport layer 40 is arranged. On top of the second charge carrier transport layer 40, a p-type contact layer 50 also acting in this embodiment as a structured mask is provided.

In accordance with the present invention, the aluminium content of the barrier layers 31a, 31b and 31c in the active region lies in the range for [(AlₓGa₁₋ₓ)_{y}In_{1-y})]_{z}P_{1-z} with x between [0.60 and 1.00], and in this particular embodiment is around x=0.8. This will raise the energy bandgap level to approximately 2.4 eV, while the aluminium content of the quantum well layer 30a and 30b corresponds to [(AlₓGa₁₋ₓ)_{y}In₁₋ₓ)]_{z}P_{1-z} with x below 0.5, corresponding to bandgap of 1.8 to 1.9 eV.

In accordance with the proposed principle, the active region 30, in particular, the barrier layers 31a, 31b and 31c are now doped with a low concentration dopant of magnesium, Mg during the growth of the respective barrier layers. Other dopants like Zn or also n-type dopants Te or Si may be suitable as well. A low concentration of dopants is referred to as low doping and is an intentional doping compared to unintentional doping or unintentional impurities. The low concentration of dopants for low doping may be in the range of about 1e16 to 3e17 atoms/cm³. As a consequence thereof, the low dopant provides a significant improvement of the quantum efficiency and thus of the device at low as well as higher current levels. Consequently, an un-doped or non-doped layer refers to a layer that is not intentionally doped. It may however still contain dopants and other impurities, which are inevitable part of the manufacturing process and cannot be avoided. Further, some diffusion of dopants from a doped region to an undoped region may take place resulting in a dopant gradient in said region.

In addition to this measure, a quantum well intermixing, QWI may be performed at the outer side edges of the respective device 1 as illustrated in FIG. 1. The dotted lines close to the edges of the device illustrate Zn diffused areas, in whose quantum well structures the QWI will take place. After structuring the contact layer 50 or deposition of a structured dielectric diffusion mask the quantum well intermixing is achieved by depositing and subsequently diffusing a p-type dopant, in particular Zn, into the p-type transport carrier layer 40 and the various quantum well layers and barrier layers of active region 30. The induced quantum well intermixing causes an increase of the energy bandgap in the area located closer to the edges of the device, thus preventing the charge carriers within the active region 30 from recombining at the sidewalls due to non-radiative surface recombination. Consequently, the ratio between radiative recombination and non-radiative recombination is shifted towards the radiative recombination.

FIG. 2 shows the variation of the dopant concentration across the various barrier and quantum well layers within the active region 30 of the device. In contrast to FIG. 1, the various layers are turned by 90° with the utmost left layer being layer 20a arranged between a doped charge transport layer 20 and active region 30. The first layer 20a comprises AlGaInP material with an aluminium content close to the first barrier layer 31a. The undoped carrier transport layer 20a is not shown in the embodiment of FIG. 1, but can be grown on the n-doped, charge carrier transport layer 20 and made of the same material.

Adjacent to the first barrier layer 31a, a first quantum well layer 32a is arranged. Following these two layers, a plurality of barrier and quantum well layers are alternating positioned on top of each other. Finally, the last barrier layer 31c is adjacent to a second charge transport layer 40.

On top of the shown structure, the concentration of the dopant is illustrated. During the growth of the various barrier and quantum layers a dopant—in particular magnesium—has been added into the respective barrier layer material. As a result, the dopant concentration is relatively large at the location of the barrier layers. No adding with magnesium or any other dopant occurs in this example during the growth of the quantum well layers, but only during the deposition of the respective barrier layers. However, due to diffusion of the respective dopant, the concentration of the dopant inside the quantum well layer is not zero but drops to a smaller level. This level is depending on the diffusion, which in turn can be controlled by the growth process and/or any subsequent annealing step. As a result, the dopant concentration becomes modulated across the active region and only decreases in the adjacent carrier transport layers 20a and 40.

The modulation of a concentration due to the illustrated diffusion can be adjusted in accordance with the needs and desires for the respective device. For example, doping can occur only during the growth of the respective barrier layers as illustrated. However, it is also possible to add dopant during the growth of the quantum well layers. The doping material can be the same but can also vary in the different barriers. In some aspects doping with magnesium, Mg or any other suitable dopants is performed only during a deposition of certain layers within active region and not, as illustrated in each barrier layer. For example, adding of dopant may occur only in the central layer of the active region, only in the layers adjacent to the carrier transport layers or only in each third or fourth layer.

Alternatively, the dopant concentration can also vary during the adding of the dopant itself. For example, the doping level can increase or decrease within the respective layers when starting from the first barrier layer 31a. It has been found that a dopant concentration in the range of 1e16 atoms/cm³ to 3e17 atoms/cm³ provides an improvement of the device and performance increase while higher doping concentrations in the range of 1e18 atoms/cm³ is detrimental.

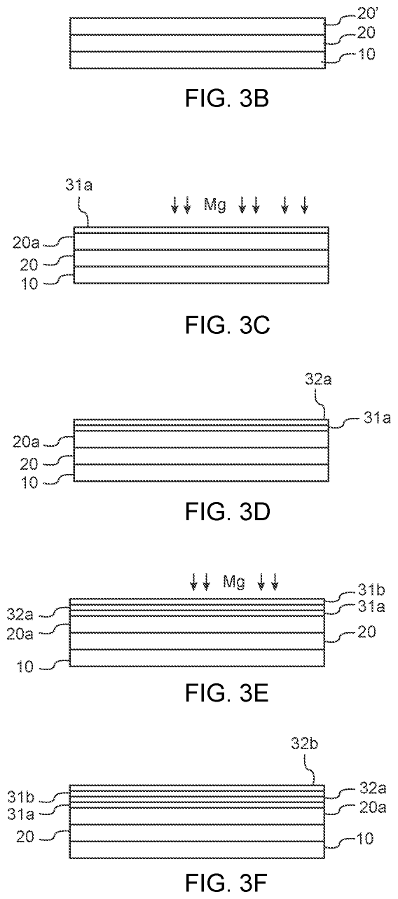

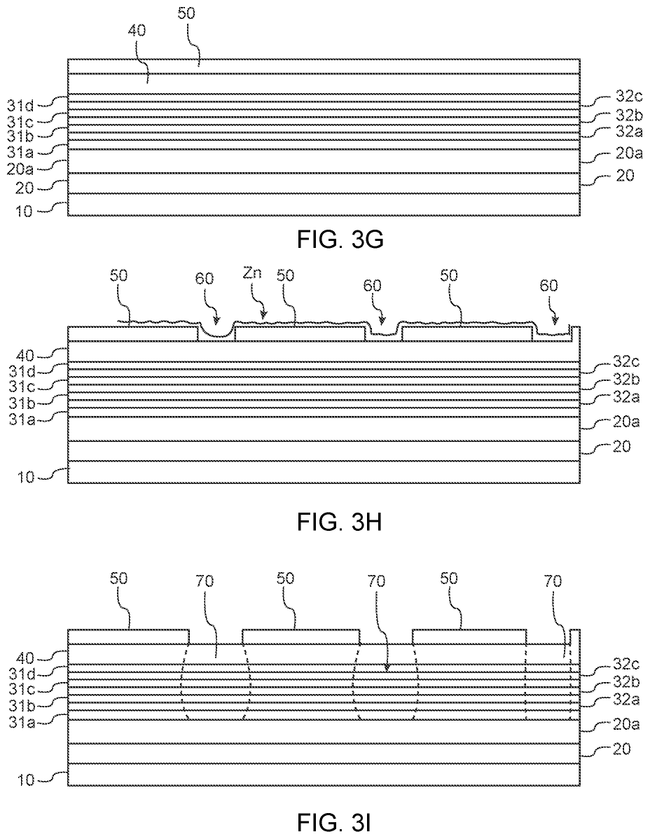

FIG. 3A to 3I illustrates the manufacturing of an optoelectronic device in accordance with the proposed principle.

In FIG. 3A, a growth substrate 10 is provided on which the first charge carrier transport layer 20 is grown. In this embodiment, the charge carrier transport layer 20 is an n-type doped AlGaInP base with [(AlₓGa₁₋ₓ)_{y}In_{1-y}]_{z}P_{1-z} having an aluminium content of approximately x between 0.5 and 1.0). Parameter y and z are in the range of 0.47 to 0.53. Between the first of transport layer 20 and growth substrate 10, a couple of sacrificial or other layers can be grown adjusting the lattice constant but also providing a smooth surface for the subsequently grown semiconductor layers.

On top of the first n-type doped carrier transport layer 20 an undoped layer 20a is arranged. The deposition can be easily achieved by reducing or otherwise changing the dopant concentration when growing the AlGaInP layer 20. It should be noted that other dopant concentrations for layer 20a can be easily adjusted to reflect the needs for the device.

In FIG. 3C, the first barrier layer 31a of the active region is grown on the undoped layer 20a with [(AlₓGa₁₋ₓ)_{y}In_{1-y}]_{z}P_{1-z} having an aluminium content of x between 0.7 and 0.8). The growth speed for the respective barrier layer 31a can be reduced such that only a few layers of atoms are grown per minute. The overall thickness of the first barrier layer may be in the range of 3 to 20 nm. During the growth of the material of the first barrier layer, a dopant (in this particular example magnesium) is added, thus providing a low dopant concentration in the first barrier layer 31a. The dopant concentration is set to be around to 2e16 atoms/cm³.

On top of the first barrier layer 31a, as shown in FIG. 3D, a first quantum well layer 32a is grown. The aluminium content of this first quantum well layer 32a is significantly lower than the aluminium content of the first barrier layer 31a and may be in the range lower than x=0.5. Furthermore, no further dopant is added during the deposition of the material forming the first quantum well layer. The thickness of the quantum well layer 32a is selected to be in the same range as the barrier layer but can also be slightly smaller than the respective first barrier layer 31a. The reduced aluminium content results in a slimmer bandgap level of approximately 1.9 eV to 2.0 eV, compared to the barrier layer, which has a bandgap in the range of 2.4 eV.

In a subsequent step illustrated in FIG. 3E, a second barrier layer 31b is grown on the first quantum well layer while the dopant element is added during the deposition phase. The thickness of the second barrier layer 31b is in this example in the same range as the thickness of the first barrier layer, but may also be adjusted, for example can be larger or smaller than the first barrier layer 31a. In a subsequent step illustrated in FIG. 3F, a second quantum well layer 32b is grown again with no additional dopant being added during the deposition of the material.

The steps of the stacking alternating barrier and quantum well layers can be repeated until the desired structure of the active region is formed. As shown in this example, during the growth of the respective barrier layers, magnesium, Mg is added as a dopant during the deposition phases of the barrier layer material. In the particular embodiment, the adding of magnesium, Mg takes place slightly after the growth of the material of the respective barrier layers has begun and a first atomic layer has been grown. In other words, the adding of magnesium as a dopant is slightly delayed during the growth and will terminate slightly before ending the deposition of the respective barrier layer material.

FIG. 3G shows as a structure of the active region formed on the carrier transport layer 20 with exemplary three quantum well layers 32a, 32b and 32c, and in total four barrier layers 31a to 31d. On top of the last barrier layer 31d, the second p-type carrier transport layer 40 is grown. A contact layer 50 with a high p-dopant concentration is arranged on top of that second carrier transport layer 40.

The now existing structure resembles an optoelectronic device with an improved performance due to the low but well-defined concentration of dopant within certain layers of the active region. Similar to the previous embodiment, a modulation of the dopant concentration across the active region is achieved due to the diffusion of the dopant material Mg in adjacent quantum well layers. Said diffusion can be controlled to some extent by an annealing step either after the generation of the active region or after certain steps during the growth of the barrier layers and the quantum well layers, respectively.

A further improvement of the optoelectronic device can be achieved by additionally providing quantum well intermixing in certain areas of the active region. The areas selected for quantum well intermixing are closer to edges of the subsequently finalised optoelectronic device. For this purpose, the contact layer 50 is structured to provide openings 60 thereby exposing the surfaces of the p-type doped second carrier transport layer 40. Then in a subsequent step, dopant material Zn is deposited on the surfaces of the second carrier transport layer 40 as well as on the surface of the structured contact layer 50.

The deposition of Zn as a dopant is performed at a first relatively low temperature. This will prevent unintentional diffusion into the various layer and thus a better control of the diffusion depth is achieved. Subsequently the Zn dopant is diffused into the p-type carrier transport layer 40 as well as the active region 30 and the respective barrier and quantum well layers at a second temperature larger than the first temperature.

Due to the structured contact layer 50, the area in which such a quantum well intermixing takes place does not expand in the quantum well and barrier layers below the structured contact layer 50. To this extent, contact layer 50 acts as a diffusion mask. As a result, illustrated in FIG. 3I, the quantum well intermixed areas 70 are located at certain positions within the semiconductor material and the active region 30. The zinc diffused areas extend through the active region 30 close to the undoped layer 20a. The areas selected for quantum well intermixing are positioned at locations later used to separate the various devices thus forming the side edges of the respective devices. The bandgap in the quantum well intermixed areas increases such that charge carriers are facing a repelling electrical field preventing them from reaching the outer edges of the device, at which the surface recombination is highest. Together with the intentional low doping of the active region, the performance and quantum efficiency of the device can be increased further.

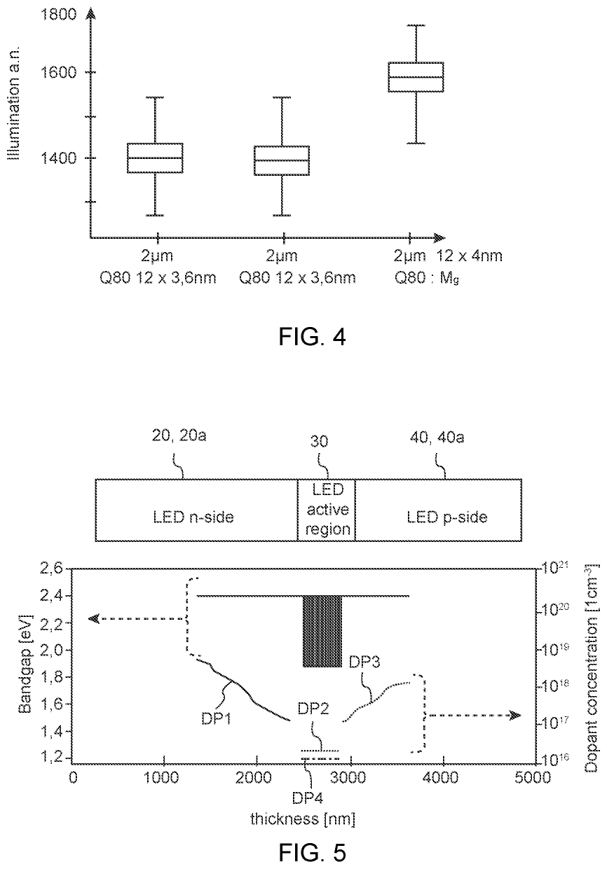

FIG. 4 shows a diagram illustrating the performance increase of an optoelectronic device and the method of manufacturing the same in accordance with the proposed principle in comparison with devices fabricated without intentional doping of the active layer. The y-axis of the diagram shows the light output power in arbitrary units starting from approximately 1200 units as its lower end and ending at about 1800 units.

Three examples are presented corresponding to a plurality of optoelectronic devices manufactured in the different ways. The first two optoelectronic device examples are based on the AlGaInP material system using an aluminium content in the barrier layers of x=0.8, as well as 12 unintentionally doped quantum well layers, each layer 3.6 nm wide. The optoelectronic devices measured in these instances comprise roughly a median illumination value of 1400 units with its 95% confidence interval reaching from approximately 1250 units to 1550 units. As a result, without the additional doping in the active region about 50% of the optoelectronic devices manufactured by this conventional method have an illumination of 1400 units.

In contrast, utmost right element corresponds to optoelectronic devices with the same aluminium content in the barrier layers as well as 12 quantum well layers, each of them having a thickness of 4 nm. In addition, the active region has been doped in the barrier layers with magnesium as a dopant. As shown in this illustration, the majority of electronic devices manufactured in this way have an illumination value roughly 200 units larger than the devices without magnesium doping with a median at approximately 1600 unit. The 95% confidence interval reaches from 1400 units to approximately 1800 units. This means that the additional doping provides a performance improvement of about 14%.

Apart from the additional dopant in the active region, it is also noted that the thickness of the quantum well layers are with 4 nm about 10% larger than in the two previous examples with 3.6 nm. However, that additional thickness should usually result in a lower illumination value and not—as it is illustrated—in a significantly increased illumination. Consequently, one can assume that quantum well layer thickness of 3.6 nm will even boost the performance further when intentionally doping the active region with a low concentration. In fact, it has been observed that an increase of Mg in the active region does improve the internal quantum efficiency until a maximum is reached beyond that a detrimental effect kicks in, increasing the non-radiative recombination.

FIG. 5 illustrates an example of a doping process in an optoelectronic device in accordance with the proposed principle together. The diagram also illustrates the course of the doping over the thickness of the various layers, the respective bandgap and the concentration level of the dopant. Actual doping levels may vary as the dopants may diffuse into adjacent layers. Consequently, the embodiment is an exemplary embodiment and can be varied with different layers, dopant levels and so forth.

The n-type side comprises a thickness of approximately 1500 nm and includes an aluminium content in the material with x in the range of 0.7 to 1.0. The n-doped layer comprises a dopant level with an n-type dopant DP1, using for instance tellurium or silicon. As shown in the diagram, the dopant concentration may vary and generally decreases when getting closer to the active region, starting with a dopant level of approximately 2e18 atoms/cm³. Following the n-type carrier transport layer 20 and 20a on the n-side, the active region 30 starts at approximately 2,500 nm. The active region 30 comprising a plurality of quantum barrier and quantum well layers is located adjacent to the undoped region.

As shown in the diagram, a second dopant DP2 with a lower concentration in the range of a few 10¹⁶ atoms/cm³ is added during the deposition and manufacturing of the active region, that is during growth of the various barrier and quantum well layers. This additional dopant comprises a slightly larger concentration than the unintentional existing dopant DP4, which mainly comprises of impurities and crystal defects. The unintentional doping DP4 lies in the range below 1e16 atoms/cm³ and as such this is an order of magnitude lower than the intentional low doping level of material DP2.

The material used for DP2 may comprise Zn or Mg for p-type dopants as well as silicon, Si or tellurium Te as n-type dopants. It has been found that magnesium as a p-type dopant is beneficial in terms of performance increase of the respective device. Adjacent to the active region 30, a p-doped layer structure is grown. The p-type layer structure includes a second dopant DP3 which raises from an initial concentration level of approximately 1e17 atoms/cm³ to about 1e18 atoms/cm³. Consequently the doping concentration between the n-side 30, 30a and the p-side 40,40a may not only vary with regards to their minimum and maximum level, but may also differ in this actual course of doping as illustrated.

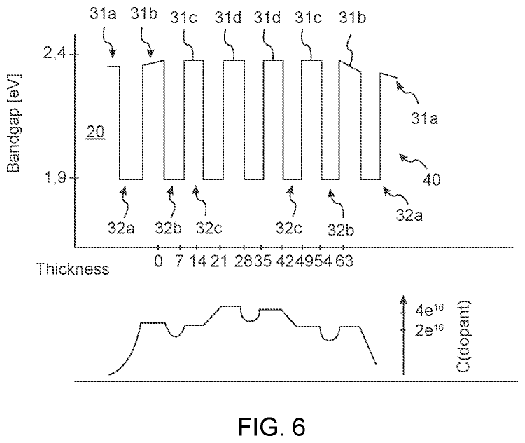

FIG. 6 illustrates a more detailed view of an active region with a plurality of barrier and quantum well layers in accordance with some aspects of the proposed principle. The thickness of the quantum well layers as well as barrier layers are approximately 7 nm, and as such, barrier layers and quantum well layer have equal distance to each other. However, in some instances and embodiments, the thickness of the quantum well layers can be smaller than the corresponding thickness of adjacent barrier layers.

The aluminium content in the quantum well layer comprises a value x in the range between 0 and 0.5, while the aluminium content in the barrier layers reaches about x=0.8. Consequently, the AlGaInP barrier layers with the large Al content provides a band gap of approximately 2.4 eV, while the band gap within the quantum well layers lies at about 1.9 eV.

In the lower portion of the FIG. 6, the doping level for the various barrier and quantum well layers is illustrated. As in the previous examples, the doping with Mg, Zn, Te or Si is only performed during growth of the respective barrier layers, with adding the dopant shortly after growth of the respective layer has begun and stopping the dopant shortly before end of growth.

No dopant is added during the growth of the material forming the quantum well layer. Consequently, the concentration of the dopant varies between the different layers. Furthermore, different dopant concentrations were selected for the barrier layers. In particular, the first two barrier layers 31b and 31c on the left side (close to layer 20a) comprises the same doping level as the barrier layer 31c and 31b at the right side adjacent to the p-type doped carrier layer. The concentration level of dopant for those barrier layers is in the range of 2e16 atoms/cm³. The two centrally arranged barrier layers 31d comprise a higher concentration of dopant in the range of about 4e16 atoms/cm³. It becomes apparent that the doping level in the quantum well layer changes due to diffusion of the dopant from the barrier layers into the quantum well layers. As a result, the dopant concentration in the quantum well layer 32b decreases from the adjacent dopant concentration 2016 atoms/cm³ to approximately 1e16 atoms/cm³. The adjacent quantum well layers 32c comprise an increasing dopant concentration in a substantial linear manner from 2e16 atoms/cm³ to 4e16 atoms/cm³. This is due to the different doping level between the barrier layer 31d and 31c, respectively. Outside of the outermost quantum well layer 32a the dopant concentration continuously decreases.

This example illustrates the various implementation possibilities for a lower level of doping in the active region of an optoelectronic device in accordance with the present invention. As can be seen from the examples, due to diffusion the dopant concentration may vary in the respective individual barrier and quantum well layers and is inhomogeneous throughout the barrier. Still, the diffusion can be used to provide a desired concentration profile, as illustrated in FIG. 6 and FIG. 2, respectively.

1.-21. (canceled)

22. A method for manufacturing an optoelectronic device, the method comprising:
providing a growth substrate layer;
depositing a first doped [(AlₓGa₁₋ₓ)_{y}In_{1-y}]_{z}P_{1-z} carrier transport layer on the substrate layer with x in a range of [0.5;1] along a growth direction; and
depositing an active region along the growth direction, the active region for generating radiation and comprising a plurality of alternating [(AlₐGa₁₋ₐ)_{b}In_{1-b}]_{c}P_{1-c} quantum well layers and [(AlₐGa_{1-d})ₑIn₁₋ₑ]_{f}P_{1-f} barrier layers, wherein a is in a range of [0;0.5] and d is in a range of [0.45;1.0],
wherein depositing of at least one of the barrier layer and/or the quantum well layer comprises:
doping with a dopant having a concentration in a range of 1e¹⁵ atoms/cm³ to 5e¹⁷ atoms/cm³, wherein the dopant is selected from at least one of the group consisting of Mg, Zn, Te and Si; or
depositing a second doped carrier transport [(AlₓGa₁₋ₓ)_{y}In_{1-y}]_{z}P_{1-z} layer with x in a range of [0.45;1] along the growth direction.

23. The method according to claim 22, wherein the doping takes place of at least one quantum barrier layer.

24. The method according to claim 22, wherein the concentration of the dopant varies while doping.

25. The method according to claim 22, wherein doping with the dopant takes place after depositing of a material for the at least one of the barrier layer or the quantum well layer has started and ends prior to stopping depositing of the material for the at least one of the barrier layer or the quantum well layer;

26. The method according to claim 22, wherein depositing the active region comprises depositing between 3 and 30 quantum well layers, inclusive, whereas the quantum well layers each comprise a thickness between 2 nm und 15 nm, inclusive, and quantum barrier layers each comprise a thickness between 3 nm und 25 nm, inclusive.

27. The method according to claim 22, wherein depositing the active region comprises annealing, at a temperature range between 450° C. and 600° C., inclusive, the deposited plurality of alternating quantum well layers and barrier layers.

28. The method according to claim 22, wherein depositing the first doped carrier transport layer comprises depositing an un-doped [(AlₓGa₁₋ₓ)_{y}In_{1-y}]_{z}P_{1-z} layer prior to depositing the active region.

29. The method according to claim 22,
wherein at least some of the plurality of barrier layers comprise different Al content with respect to each other,
wherein a Al content within each barrier layer is constant, and/or
wherein a minimum and maximum Al content of the different layers within the active region is different by a factor in a range of 1.1 to 3.5.

30. The method according to claim 22,
wherein at least some of the barrier layers comprise different thicknesses, and
wherein a minimum and a maximum thickness of the barrier layers in the active region differ by a factor between 1.5 and 6, inclusive.

31. The method according to claim 22, wherein y and z are each in a range of [0.45;0.55] and b and c are in a range of [0.45;0.55]

32. The method according to claim 22, further comprising:
depositing a structured mask layer; and
depositing and diffusing a dopant through the second doped carrier transport [(AlₓGa₁₋ₓ)_{y}In_{1-y}]_{z}P_{1-z} layer into the active region to obtain quantum well intermixed areas.

33. The method according to claim 32, wherein the dopant is deposited at a first temperature and diffused at a second temperature, the second temperature being higher than the first temperature.

34. The method according to claim 32, wherein the dopant is Zn.

35. The method according to claim 32, wherein diffusing the dopant through the second doped carrier transport layer comprises providing AsH₃ or any other group V containing gas.

36. An optoelectronic device, comprising:
a first doped carrier transport [(AlₓGa₁₋ₓ)_{y}In_{1-y}]_{z}P_{1-z} layer with x in a range of [0;0.5];
an active region arranged on the first doped carrier transport layer, the active region configured to generate radiation and comprising a plurality of alternating [(AlₐGa₁₋ₐ)_{b}In_{1-b}]_{c}P_{1-c} quantum well layers and [(AlₐGa_{1-d})ₑIn₁₋ₑ}_{f}P_{1-f} barrier layers, wherein a is in a range of [0;0.5] and d is in a range of [0.45;1.0]; and
a second doped carrier transport [(AlₓGa₁₋ₓ)_{y}In_{1-y}]_{z}P_{1-z} layer arranged on the active region with x in a range of [0;0.5],
wherein at least one of the plurality of quantum well layers and/or the barrier layers comprise a dopant having a concentration in a range of 1e¹⁵ atoms/cm³ to 5e¹⁷ atoms/cm³ and with the dopant selected from at least one of the group consisting of Mg, Zn, Te and Si.

37. The optoelectronic device according to claim 36, wherein the active region comprises between 3 and 30 quantum well layers, inclusive, whereas the quantum well layers each comprise a thickness between 2 nm und 15 nm, inclusive and the quantum barrier layers each comprise a thickness between 3 nm und 25 nm, inclusive.

38. The optoelectronic device according to claim 36, further comprising:
a layer with a decreasing dopant concentration arranged between at least one of the first doped carrier transport layer and the active region; and/or
a layer with an increasing dopant concentration arranged between the active region and the second doped carrier transport layer.

39. The optoelectronic device according to claim 36,
wherein at least some of the plurality of barrier layers comprise different Al content with respect to each other,
wherein an Al content within each barrier layer is constant, and/or
wherein a minimum and a maximum Al content between the different layers within the active region is different by a factor in a range of 1.1 to 3.5.

40. The optoelectronic device according to claim 36, wherein the dopant in the active region extends over a plurality of alternating quantum well layers and barrier layers.

41. The optoelectronic device according to claim 36, further comprising a quantum well intermixed area having a dopant concentration larger than a dopant concentration in a non-intermixed area, wherein the dopant comprises Zn.

42. The optoelectronic device according to claim 41, wherein the quantum well intermixed area is adjacent to an edge interface of the optoelectronic device.
